(19) United States
(12) Patent Application Publication
(10) Pub. No.: US 2010/0101641 A1
(43) Pub. Date: Apr. 29, 2010

(54) SOLAR CELL COATING AND METHOD FOR MANUFACTURING THE SAME

(75) Inventors: WEI-FANG SU, Taipei City (TW); I-SHUO LIU, Taipei City (TW); MING-CHUNG WU, Taipei City (TW); KUO-TUNG HUANG, Taipei City (TW); TSUN-NENG YANG, Taipei City (TW); CHENG-SI TSAO, Taoyuan County (TW)

Correspondence Address: WPAT, PC;INTELLECTUAL PROPERTY ATTORNEYS, 7225 BEVERLY ST., ANNANDALE, VA, 22003, US

(73) Assignee: INSTITUTE OF NUCLEAR ENERGY RESEARCH ATOMIC ENERGY COUNCIL, EXECUTIVE YUAN, Taoyuan County (TW)

(21) Appl. No.: 12/497,833

(22) Filed: Jul. 6, 2009

(30) Foreign Application Priority Data
Oct. 24, 2008 (TW) 097140986

(51) Int. Cl. H01L 31/0264; H01L 21/20

(52) U.S. Cl. 136/256; 438/63; 257/E21.09; 977/773; 257/E31.004

(57) ABSTRACT

A solar cell coating and a method for manufacturing the solar cell coating. The solar cell coating is formed by adding a low bandgap material, a semiconductor material and a conductive polymer to a solvent or performing high-temperature milling on a mixture formed by mixing a conductive polymer material, a low bandgap material and a semiconductor material so that the solar cell coating exhibits high capability in transporting carriers effectively to transmit the electrons and holes to respective electrodes rapidly. Since the low bandgap material exhibits a small bandgap, MEG takes place to generate a plurality of electro-hole pairs when a photon is absorbed by the low bandgap material. Besides, by mixing the three materials corresponding to different conductive and valence bands respectively, a ladder structure formed by the HOMO and the LUMO corresponding to the three materials respectively will assist effective and rapid carrier transport.

### FIELD OF PRESENT INVENTION

The present invention generally relates to a solar cell material and a method for manufacturing the same and, more particularly, to a solar cell coating and a method for manufacturing the solar cell coating by mixing different materials.

### BACKGROUND OF THE PRESENT INVENTION

As the amounts of conventional resources such as electricity, coal and petroleum are limited, the resource problems have become a bottleneck of economic growth. More and more countries have launched researches on solar energy as a potential motive force for economic development. The solar energy, as a renewable energy resource, has attracted tremendous amount of attention. The solar energy is realized using solar cells with less power consumption and environment friendliness. In recent years, with the increasing demand in the solar energy, the manufacturing technology has advanced significantly. Therefore, the solar energy has been the fastest developing industry.

In order to convert the solar energy into electrical energy, the solar cells are inevitable. The solar cell is a diode device with a p-n semiconductor junction, whereat the photoelectric effect is used to generate electricity. When a photon is absorbed on the surface of a diode to generate excitons, the built-in electric field in the depletion region at the p-n junction unbind the excitons to generate electrons and holes transmitted to respective electrodes to induce a current and thus construct a solar cell.

Because of the importance of the solar cell, lots of efforts have been made on the efficiency as well as manufacturing of the solar cell in a material aspect to achieve efficient and rapid carrier transport. For example, in “Solar Cells based on quantum dots: Multiple exciton generation and intermediate bands,” MRS BULLETIN, Volume 32, March 2007, by Antonio Luque et al., an n-type porous semiconductor titanium dioxide (TiO₂) layer is formed on a conductive substrate. Generally, the porous titanium dioxide layer is formed by sintering titanium dioxide particles and depositing a p-type indium phosphide (InP) quantum dot material on the porous titanium dioxide to form a solar cell with a p-n junction. Moreover, in this paper, a quantum dot material such as cadmium selenide (CdSe) is mixed with hole-conductive polymer (poly(2methoxy, 5-(2′-ethyl)-hexyloxy-p-phenylenevinylene), referred to as MEH-PPV) and electron-conductive polymer to form a solar cell with a multi-layered p-n junction.

Moreover, in “Quantum Dot Sensitization of Organic-Inorganic Hybrid Solar Cells,” J. Phys. Chem. B 2002, 106, 7578-7580, by Robert Plass et al., a solar cell formed of a mixture of an organic material and an inorganic material is disclosed. Like Antonio Luque et al., Robert Plass et al. use high-temperature sintering to make titanium dioxide porous and then deposit lead sulfide (PbS) quantum dots on the TiO₂ substrate by chemical vapor-phase deposition (CVD). Later, the TiO₂ substrate with PbS quantum dots is dipped in a conductive organic material such as a p-type conductive organic material (for example, spiro-OMeTAD) or is coated with a p-type polymer material (for example, MEH-PPV). The conductive organic material, titanium dioxide and lead sulfide form p-n hetero-junctions therebetween.

In the above-mentioned prior arts, three materials with different energy levels are respectively overlapped to form an the active layer of a solar cell, which is time-consuming and labor-intensive. Therefore, there is need in providing a solar cell coating and a method for manufacturing the same to overcome the aforesaid problems.

### SUMMARY OF THE PRESENT INVENTION

It is an objective of the present invention to provide a solar cell coating and a method for manufacturing the same, wherein the solar cell coating is coated on a substrate to manufacture a solar cell. The method for manufacture the solar cell coating is characterized in that nano semiconductor materials are provided with different energy levels to be mixed with a conductive polymer to form a ladder structured band lineup to assist carrier transport. Nano materials and polymer with different energy levels can be solved at the same time and distributed uniformly in a solvent to form a liquid coating. The solar cell coating can be coated by dipping, spray or spin-coating to manufacture the active layer of a solar cell.

It is another objective of the present invention to provide a solar cell coating and a method for manufacturing the same, wherein the solar cell coating is coated on a substrate to manufacture a solar cell. The method for manufacture the solar cell coating is characterized in that nano semiconductor materials are provided with different energy levels to be mixed with a conductive polymer to form a ladder structured band lineup to assist carrier transport. Nano materials and polymer with different energy levels can be mixed by high-temperature milling to form a coating with flowability. The solar cell coating can be coated by dipping, spray or spin-coating to manufacture the active layer of a solar cell.

To achieve the foregoing objectives, in one embodiment, the present invention provides a solar cell coating, comprising: a conductive polymer material corresponding to a first highest occupied molecular orbit (HOMO) and a first lowest unoccupied molecular orbit (LUMO); a low bandgap material corresponding to a second HOMO and a second LUMO, the low bandgap material being mixed with the conductive polymer material so that the low bandgap material is coupled to the conductive polymer material and the second HOMO and the second LUMO have lower energy than the first HOMO and the first LUMO, respectively; and a semiconductor material corresponding to a third HOMO and a third LUMO, the semiconductor material being mixed with the conductive polymer material so that the semiconductor material is coupled to the low bandgap material and the second HOMO and the second LUMO have higher energy than the third HOMO and the third LUMO, respectively.

In another embodiment, the present invention provides a method for manufacturing a solar cell coating, comprising steps of: providing a solvent; and forming a mixture by adding a conductive polymer material, a low bandgap material and a semiconductor material to the solvent; wherein the conductive polymer material corresponds to a first highest occupied molecular orbit (HOMO) and a first lowest unoccupied molecular orbit (LUMO), the low bandgap material corresponds to a second HOMO and a second LUMO, and the semiconductor material corresponds to a third HOMO and a third LUMO; wherein the low bandgap material is coupled to the conductive polymer material and the second HOMO and the second LUMO have lower energy than the first HOMO and the first LUMO, respectively, and the semiconductor material is coupled to the low bandgap material and the second HOMO and the second LUMO have higher energy than the third HOMO and the third LUMO, respectively.

In another embodiment, the present invention provides a method for manufacturing a solar cell coating, comprising steps of: forming a mixture by mixing a conductive polymer material, a low bandgap material and a semiconductor material; and forming a liquid mixture with flowability by performing high-temperature milling on the mixture; wherein the conductive polymer material corresponds to a first highest occupied molecular orbit (HOMO) and a first lowest unoccupied molecular orbit (LUMO), the low bandgap material corresponds to a second HOMO and a second LUMO, and the semiconductor material corresponds to a third HOMO and a third LUMO; wherein the low bandgap material is coupled to the conductive polymer material and the second HOMO and the second LUMO have lower energy than the first HOMO and the first LUMO, respectively, and the semiconductor material is coupled to the low bandgap material and the second HOMO and the second LUMO have higher energy than the third HOMO and the third LUMO, respectively.

### BRIEF DESCRIPTION OF THE DRAWINGS

The objectives and spirits of several embodiments of the present invention will be readily understood by the accompanying drawings and detailed descriptions, wherein:

FIG. 1 shows the energy band diagrams of different materials of a solar cell coating according to the present invention;

FIG. 2A is a flowchart of a method for manufacturing a solar cell coating according to one embodiment of the present invention;

FIG. 2B is a flowchart of a method for manufacturing a solar cell coating according to another embodiment of the present invention;

FIG. 3 schematically depicts carrier transport in a solar cell coating according to the present invention; and

FIG. 4 shows a PL intensity to wavelength relation as comparison between the present invention and the prior art.

### DETAILED DESCRIPTION OF THE PREFERRED EMBODIMENT

The present invention can be exemplified but not limited by various embodiments as described hereinafter.

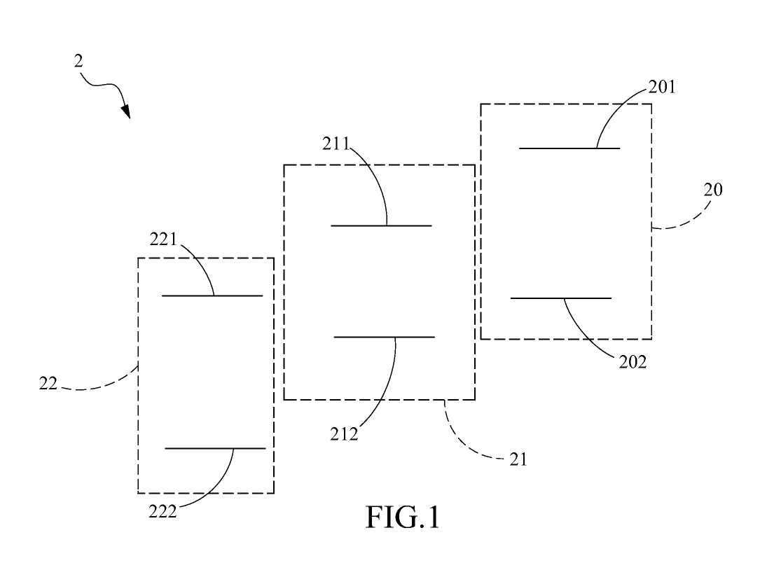

Please refer to FIG. 1, which shows the energy band diagrams of different materials of a solar cell coating according to the present invention. The solar cell coating 2 comprises a conductive polymer material 20, a low bandgap material 21 and a semiconductor material 22. The conductive polymer material 20 corresponds to a first highest occupied molecular orbit (HOMO) 202 and a first lowest unoccupied molecular orbit (LUMO) 201. In the present embodiment, the conductive polymer material 20 is a p-type conductive polymer material, which can be a nano-scale conjugated polymer material such as MEHPPV, P3HT (poly(3-hexylthiophene)) or derivatives thereof and is not limited thereto. The low bandgap material 21 corresponds to a second highest occupied molecular orbit (HOMO) 212 and a second lowest unoccupied molecular orbit (LUMO) 211. The low bandgap material 21 is mixed with the conductive polymer material 20 so that the conductive polymer material 20 is coupled to the low bandgap material 21 and the second highest occupied molecular orbit (HOMO) 212 and the second lowest unoccupied molecular orbit (LUMO) 211 have lower energy than the first highest occupied molecular orbit (HOMO) 202 and the first lowest unoccupied molecular orbit (LUMO) 201, respectively. In the present embodiment, the low bandgap material is a nano semiconductor material wherein multiple exciton generation (MEG) takes place. The nano semiconductor material comprises nano particles formed of Bi₂Se₃, Bi₂S₃, CdTe, GaAs, HgSe, HgTe, InAs, InP, InSb, PbS, PbSe, PbTe, CuInSe₂, CuInS₂, Si or Ge.

The semiconductor material 22 corresponds to a third highest occupied molecular orbit (HOMO) 222 and a third lowest unoccupied molecular orbit (LUMO) 221 and is mixed with the conductive polymer material 20. The semiconductor material 22 is coupled to the low bandgap material 21. The second highest occupied molecular orbit (HOMO) 212 and the second lowest unoccupied molecular orbit (LUMO) 211 have higher energy than the third highest occupied molecular orbit (HOMO) 222 and the third lowest unoccupied molecular orbit (LUMO) 221. The semiconductor material is a nano-scale organic semiconductor material or a nano-scale inorganic semiconductor material. The inorganic semiconductor material is an n-type nano-scale inorganic material. In the present embodiment, the inorganic material comprises titanium dioxide (TiO₂), zinc oxide (ZnO) or tin dioxide (SnO₂). The organic semiconductor material comprises polyvinylcarbazole and is not limited thereto.

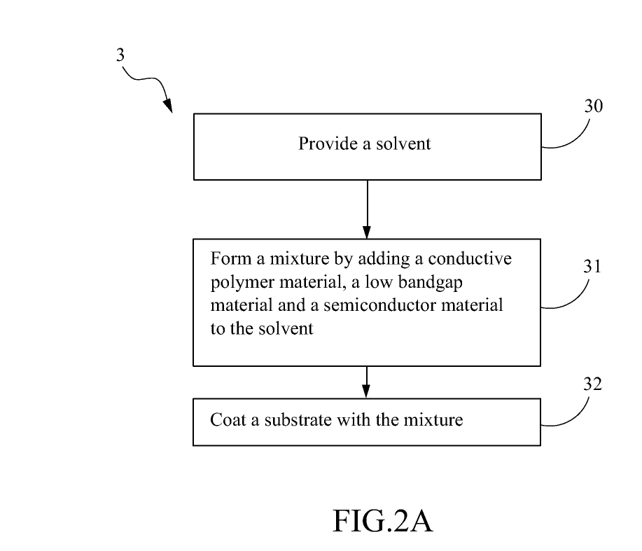

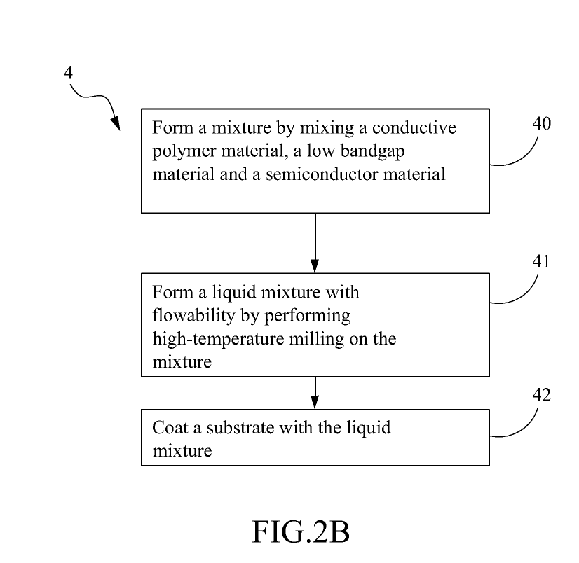

Please refer to FIG. 2A, which is a flowchart of a method for manufacturing a solar cell coating according to one embodiment of the present invention. In the present embodiment, the method 3 comprises steps as described hereinafter. Firstly, step 30 is performed to provide a solvent. The solvent comprises benzene, chloroform, toluene, chlorobenzene, dichlorobenzene, trichlorobenzene, tetrahydrofuran, pyridine or or combination thereof and is not limited thereto. Then in step 31, a mixture is formed by adding a conductive polymer material, a low bandgap material and a semiconductor material to the solvent so that the semiconductor material, the low bandgap material and the conductive polymer material are uniformly mixed. To achieve uniformity of the mixture, the semiconductor material and low bandgap material comprise nano particles. The conductive polymer material, the low bandgap material and the semiconductor material comprise materials are as stated above and thus descriptions thereof are not repeated. Moreover, the method 3 further comprises a step 32 of coating a substrate with the mixture so as to form a solar energy substrate with photoelectric conversion. The substrate can be coated by conventional techniques such as spin-coating, spray or scraping, and detailed description thereof is not represented.

Moreover, in FIG. 2B, a flowchart of a method for manufacturing a solar cell coating according to another embodiment of the present invention is shown. The method 4 in the embodiment comprises steps as described hereinafter. Firstly, step 40 is performed to form a mixture by mixing a conductive polymer material, a low bandgap material and a semiconductor material. The conductive polymer material, the low bandgap material and the semiconductor material comprise materials are as stated above and thus descriptions thereof are not repeated. Then in step 41, a liquid mixture with flowability is formed by performing high-temperature milling on the mixture. Moreover, the method 4 further comprises a step 42 of coating a substrate with the liquid mixture so as to form a solar energy substrate with photoelectric conversion. The substrate can be coated by conventional techniques such as injecting, extruding or spin-coating.

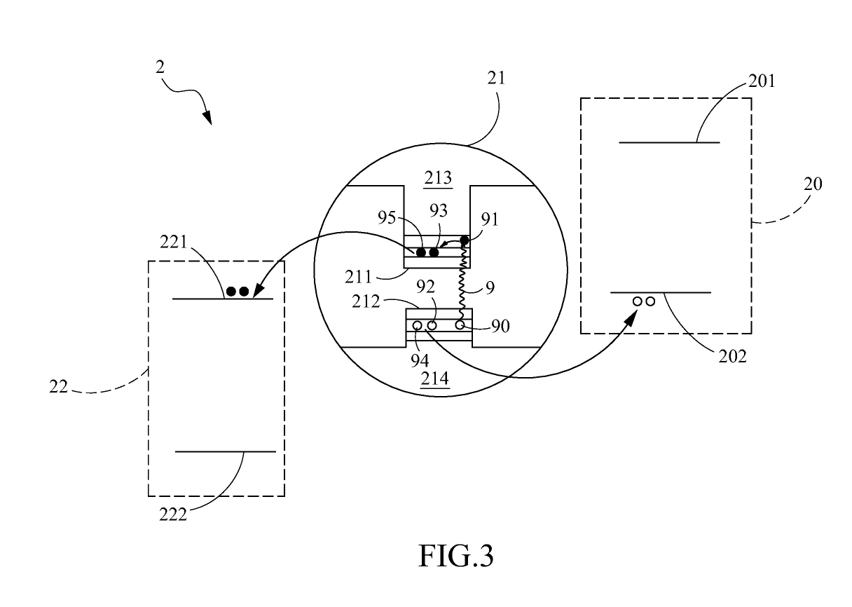

Please refer to FIG. 3, which schematically depicts carrier transport in a solar cell coating according to the present invention. Taking a structure formed of TiO₂/CuInSe₂/P3HT for example, CuInSe₂ is the low bandgap material 21, TiO₂ is the semiconductor material, and P3HT is the polymer substrate. When a light beam 9 is incident on a material 21, electrons 91 are excited from the valance band 214 to the conduction band 213 so that holes 90 are simultaneously generated in the valance band 214. On the other hand, since the material 21 is a low bandgap material, multiple excitons (electron-hole pairs) are generated as the electrons 91 are excited from the valance band 214 to the conduction band 213. Moreover, the TiO₂/CuInSe₂/P3HT structure is a ladder structure corresponding to the energy levels of the highest occupied molecular orbits (HOMO) and the lowest unoccupied molecular orbits (LUMO). In other words, the HOMO corresponding to TiO₂ has lower energy than the HOMO corresponding to CuInSe₂, and the HOMO corresponding to CuInSe₂ has lower energy than the HOMO corresponding to P3HT. Similarly, the LUMO corresponding to TiO₂ has lower energy than the LUMO corresponding to CuInSe₂, and the LUMO corresponding to CuInSe₂ has lower energy than the LUMO corresponding to P3HT. Accordingly, the electrons move towards the LUMO with lower energy, while the holes move towards the HOMO with higher energy. In this regard, the ladder structure in FIG. 3 assists electron transport from the material 22 corresponding the LUMO with lower energy.

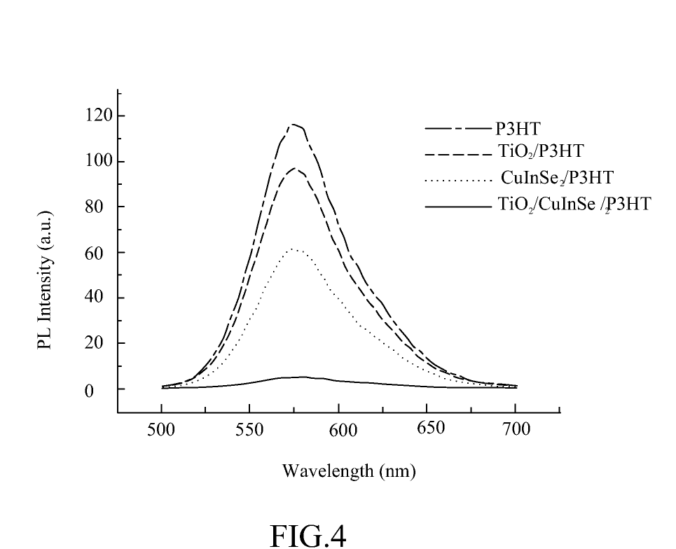

As shown in FIG. 4, a photoluminescence (PL) intensity to wavelength relation as comparison between the present invention and the prior art is shown. It is observed that the TiO₂/CuInSe₂/P3HT structure of the present invention exhibits lower PL intensity than other material structures. It indicates that most of the excitons have become separated electrons and holes to induce the current, instead of returning to the valance band while releasing energy in terms of light. On the contrary, the conventional material structures such as CuInSe₂/P3HT and TiO₂/P3HT exhibit higher PL intensity due to poor carrier transport so that most electrons are recombined with the holes to release energy in terms of light.

Accordingly, the present invention discloses a solar cell coating and a method for manufacturing the solar cell coating by mixing different materials so that the solar cell coating exhibits high capability in transporting carriers effectively to transmit the electrons and holes to respective electrodes rapidly. Therefore, the present invention is novel, useful, and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A solar cell coating, comprising:
a conductive polymer material corresponding to a first highest occupied molecular orbit (HOMO) and a first lowest unoccupied molecular orbit (LUMO);
a low bandgap material corresponding to a second HOMO and a second LUMO, the low bandgap material being mixed with the conductive polymer material so that the low bandgap material is coupled to the conductive polymer material and the second HOMO and the second LUMO have lower energy than the first HOMO and the first LUMO, respectively; and
a semiconductor material corresponding to a third HOMO and a third LUMO, the semiconductor material being mixed with the conductive polymer material so that the semiconductor material is coupled to the low bandgap material and the second HOMO and the second LUMO have higher energy than the third HOMO and the third LUMO, respectively.

2. The solar cell coating as recited in claim 1, wherein the conductive polymer material is a nano-scale conjugated polymer material.

3. The solar cell coating as recited in claim 1, wherein the conductive polymer material is a nano-scale p-type conductive polymer material.

4. The solar cell coating as recited in claim 1, wherein the low bandgap material is a nano semiconductor material wherein multiple exciton generation (MEG) takes place.

5. The solar cell coating as recited in claim 4, wherein the nano semiconductor material comprises nano particles formed of Bi₂Se₃, Bi₂S₃, CdTe, GaAs, HgSe, HgTe, InAs, InP, InSb, PbS, PbSe, PbTe, CuInSe₂, CuInS₂, Si or Ge.

6. The solar cell coating as recited in claim 1, wherein the semiconductor material is a nano-scale organic semiconductor material or a nano-scale inorganic semiconductor material.

7. The solar cell coating as recited in claim 6, wherein the inorganic semiconductor material is an n-type nano-scale inorganic material.

8. The solar cell coating as recited in claim 7, wherein the inorganic semiconductor material comprises titanium dioxide.

9. The solar cell coating as recited in claim 6, wherein the organic semiconductor material is an n-type organic semiconductor material.

10. The solar cell coating as recited in claim 9, wherein the organic semiconductor material comprises polyvinylcarbazole.

11. The solar cell coating as recited in claim 1, further comprising a solvent comprising benzene, chloroform, toluene, chlorobenzene, dichlorobenzene, trichlorobenzene, tetrahydrofuran, pyridine or combination thereof.

12. The solar cell coating as recited in claim 1, being flowable.

13. A method for manufacturing a solar cell coating, comprising steps of:
providing a solvent; and
forming a mixture by adding a conductive polymer material, a low bandgap material and a semiconductor material to the solvent;
wherein the conductive polymer material corresponds to a first highest occupied molecular orbit (HOMO) and a first lowest unoccupied molecular orbit (LUMO), the low bandgap material corresponds to a second HOMO and a second LUMO, and the semiconductor material corresponds to a third HOMO and a third LUMO;
wherein the low bandgap material is coupled to the conductive polymer material and the second HOMO and the second LUMO have lower energy than the first HOMO and the first LUMO, respectively, and the semiconductor material is coupled to the low bandgap material and the second HOMO and the second LUMO have higher energy than the third HOMO and the third LUMO, respectively.

14. The method as recited in claim 13, wherein the conductive polymer material is a nano-scale conjugated polymer material.

15. The method as recited in claim 13, wherein the conductive polymer material is nano-scale p-type conductive polymer material.

16. The method as recited in claim 13, wherein the low bandgap material is a nano semiconductor material wherein multiple exciton generation (MEG) takes place.

17. The method as recited in claim 16, wherein the nano semiconductor material comprises nano particles formed of Bi₂Se₃, Bi₂S₃, CdTe, GaAs, HgSe, HgTe, InAs, InP, InSb, PbS, PbSe, PbTe, CuInSe₂, CuInS₂, Si or Ge.

18. The method as recited in claim 13, wherein the semiconductor material is a nano-scale organic semiconductor material or a nano-scale inorganic semiconductor material.

19. The method as recited in claim 18, wherein the inorganic semiconductor material is an n-type nano-scale inorganic material.

20. The method as recited in claim 19, wherein the inorganic semiconductor material comprises titanium dioxide.

21. The method as recited in claim 18, wherein the organic semiconductor material is an n-type organic semiconductor material.

22. The method as recited in claim 21, wherein the organic semiconductor material comprises polyvinylcarbazole.

23. The method as recited in claim 13, further comprising a step of coating a substrate with the mixture.

24. The method as recited in claim 13, wherein the solvent comprises benzene, chloroform, toluene, chlorobenzene, dichlorobenzene, trichlorobenzene, tetrahydrofuran, pyridine or combination thereof.

25. A method for manufacturing a solar cell coating, comprising steps of:
forming a mixture by mixing a conductive polymer material, a low bandgap material and a semiconductor material; and
forming a liquid mixture with flowability by performing high-temperature milling on the mixture;
wherein the conductive polymer material corresponds to a first highest occupied molecular orbit (HOMO) and a first lowest unoccupied molecular orbit (LUMO), the low bandgap material corresponds to a second HOMO and a second LUMO, and the semiconductor material corresponds to a third HOMO and a third LUMO;
wherein the low bandgap material is coupled to the conductive polymer material and the second HOMO and the second LUMO have lower energy than the first HOMO and the first LUMO, respectively, and the semiconductor material is coupled to the low bandgap material and the second HOMO and the second LUMO have higher energy than the third HOMO and the third LUMO, respectively.

26. The method as recited in claim 25, wherein the conductive polymer material is a nano-scale conjugated polymer material.

27. The method as recited in claim 25, wherein the conductive polymer material is nano-scale p-type conductive polymer material.

28. The method as recited in claim 25, wherein the low bandgap material is a nano semiconductor material wherein multiple exciton generation (MEG) takes place.

29. The method as recited in claim 28, wherein the nano semiconductor material comprises nano particles formed of Bi₂Se₃, Bi₂S₃, CdTe, GaAs, HgSe, HgTe, InAs, InP, InSb, PbS, PbSe, PbTe, CuInSe₂, CuInS₂, Si or Ge.

30. The method as recited in claim 25, wherein the semiconductor material is a nano-scale organic semiconductor material or a nano-scale inorganic semiconductor material.

31. The method as recited in claim 30, wherein the inorganic semiconductor material is an n-type nano-scale inorganic material.

32. The method as recited in claim 31, wherein the inorganic semiconductor material comprises titanium dioxide.

33. The method as recited in claim 30, wherein the organic semiconductor material is an n-type organic semiconductor material.

34. The method as recited in claim 33, wherein the organic semiconductor material comprises polyvinylcarbazole.

35. The method as recited in claim 25, further comprising a step of coating a substrate with the liquid mixture.
